(19) United States
(12) Patent Application Publication
(10) Pub. No.: US 2020/0266140 A1
(43) Pub. Date: Aug. 20, 2020

(54) ELECTRONIC DEVICE, METHOD OF MANUFACTURING ELECTRONIC DEVICE, AND LEAD

(71) Applicant: SEIKO EPSON CORPORATION, Tokyo (JP)

(72) Inventor: Hisao MOTOYAMA, SUGINAMI-KU (JP)

(21) Appl. No.: 16/793,769

(22) Filed: Feb. 18, 2020

(30) Foreign Application Priority Data
Feb. 20, 2019 (JP) 2019-028168

(51) Int. Cl. H01L 23/498; H01L 23/31; H01L 23/00; H01L 21/56; H01L 21/48

(52) U.S. Cl. CPC H01L 23/49861; H01L 23/3121; H01L 21/4889; H01L 21/56; H01L 21/4853; H01L 24/45

(57) ABSTRACT

The electronic device includes an electronic component, a plurality of leads electrically coupled to the electronic component, and a mold cover covering the electronic component, wherein the plurality of leads includes an inner part located inside the mold cover, and an outer part located outside the mold cover, and the inner part includes a first lead electrically coupled to the electronic component, a second lead separated from the first lead and integrated with the outer part, and a coupling member configured to electrically couple the first lead and the second lead to each other.

The present application is based on, and claims priority from JP Application Serial Number 2019-028168, filed Feb. 20, 2019, the disclosure of which is hereby incorporated by reference herein in its entirety.

### BACKGROUND

### 1. Technical Field

The present disclosure relates to an electronic device, a method of manufacturing an electronic device, and a lead.

### 2. Related Art

In JP-A-2010-278186, there is described an electronic device constituted by an angular velocity sensor for detecting angular velocity around an X axis, an angular velocity sensor for detecting angular velocity around a Y axis, and an angular velocity sensor for detecting angular velocity around a Z axis molded with a resin package in a state of being fixed to respective leads.

However, in such a configuration as described above, a vibration and an impact generated outside the electronic device are apt to be transferred to each of the angular velocity sensors via the lead, and there is a possibility that degradation of the detection accuracy and breakage of each of the angular velocity sensors are incurred by the vibration and the impact.

### SUMMARY

An aspect of the present disclosure is directed to an electronic device including an electronic component, a plurality of leads electrically coupled to the electronic component, and a mold cover covering the electronic component, wherein the plurality of leads includes an inner part located inside the mold cover, and an outer part located outside the mold cover, and the inner part includes a first lead electrically coupled to the electronic component, a second lead separated from the first lead and integrated with the outer part, and a coupling member configured to electrically couple the first lead and the second lead to each other.

In the above aspect of the present disclosure, the coupling member may be a bonding wire.

In the above aspect of the present disclosure, gaps between the first lead and the second lead of the plurality of leads may be arranged in a line.

In the above aspect of the present disclosure, an end at the second lead side of the first lead and an end at the first lead side of the second lead may be opposed to each other.

In the above aspect of the present disclosure, the electronic device may further include a support configured to support the first lead and the second lead.

In the above aspect of the present disclosure, a constituent material of the support may be the same as a constituent material of the mold cover.

In the above aspect of the present disclosure, the electronic component may be a sensor component having a vibrator element.

Another aspect of the present disclosure is directed to a method of manufacturing an electronic device including the steps of preparing a plurality of leads including a first lead, a second lead separated from the first lead, and a coupling member configured to electrically couple the first lead and the second lead to each other, electrically coupling the electronic component to the first lead of the plurality of leads, and molding the electronic component, the first lead, the coupling member, and the second lead with a resin material.

Another aspect of the present disclosure is directed to a lead frame including a plurality of leads having a first lead to be electrically coupled to an electronic component, a second lead separated from the first lead, and a coupling member configured to electrically couple the first lead and the second lead to each other.

### BRIEF DESCRIPTION OF THE DRAWINGS

FIG. 1 is a perspective view showing an electronic device.

FIG. 2 is a cross-sectional view showing an example of an electronic component.

FIG. 3 is a cross-sectional view showing an example of an electronic component.

FIG. 4 is a plan view showing leads.

FIG. 5 is a plan view showing the leads.

FIG. 6 is a plan view showing the leads.

FIG. 7 is a plan view showing the leads.

FIG. 8 is a plan view for explaining a method of forming the leads.

FIG. 9 is a diagram showing a manufacturing process of the electronic device shown in FIG. 1.

FIG. 10 is a diagram for explaining a method of manufacturing the electronic device shown in FIG. 1.

FIG. 11 is a diagram for explaining the method of manufacturing the electronic device shown in FIG. 1.

FIG. 12 is a diagram for explaining the method of manufacturing the electronic device shown in FIG. 1.

FIG. 13 is a diagram for explaining the method of manufacturing the electronic device shown in FIG. 1.

FIG. 14 is a diagram for explaining the method of manufacturing the electronic device shown in FIG. 1.

### DESCRIPTION OF AN EXEMPLARY EMBODIMENT

Hereinafter, an electronic device, a method of manufacturing an electronic device, and a lead according to the present disclosure will be described in detail based on an embodiment shown in the accompanying drawings.

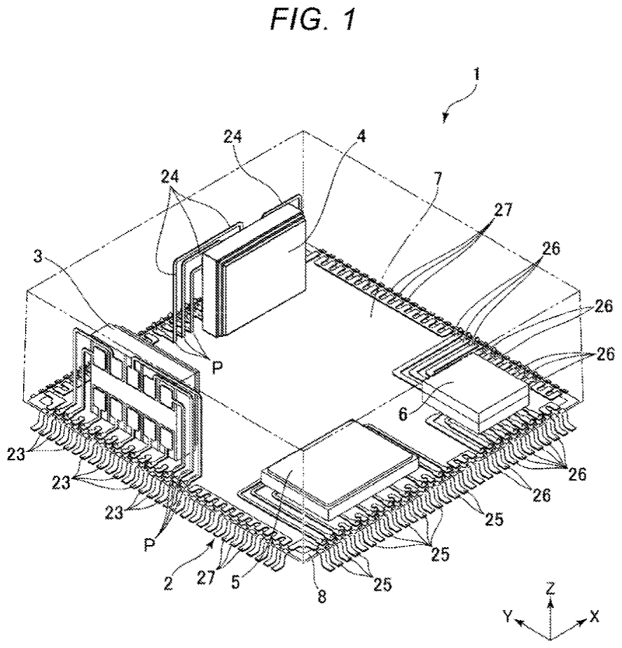

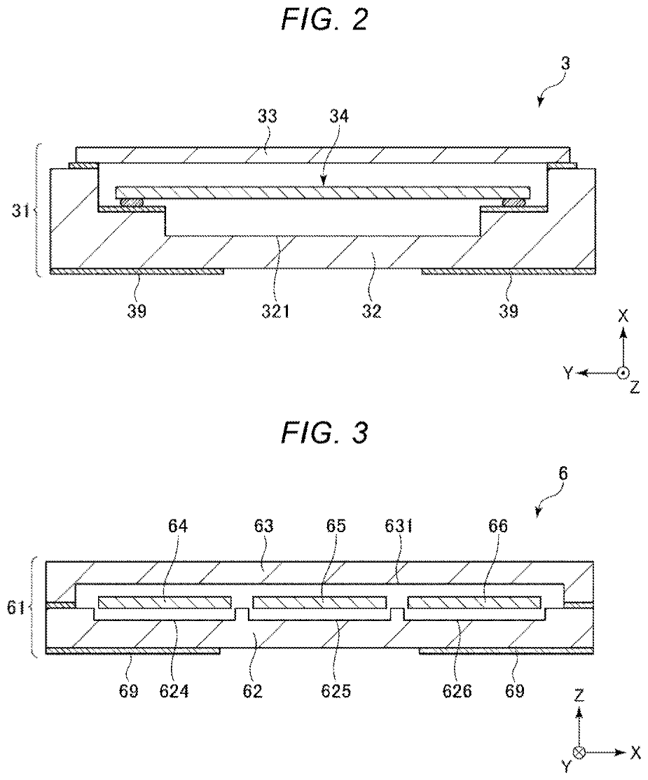

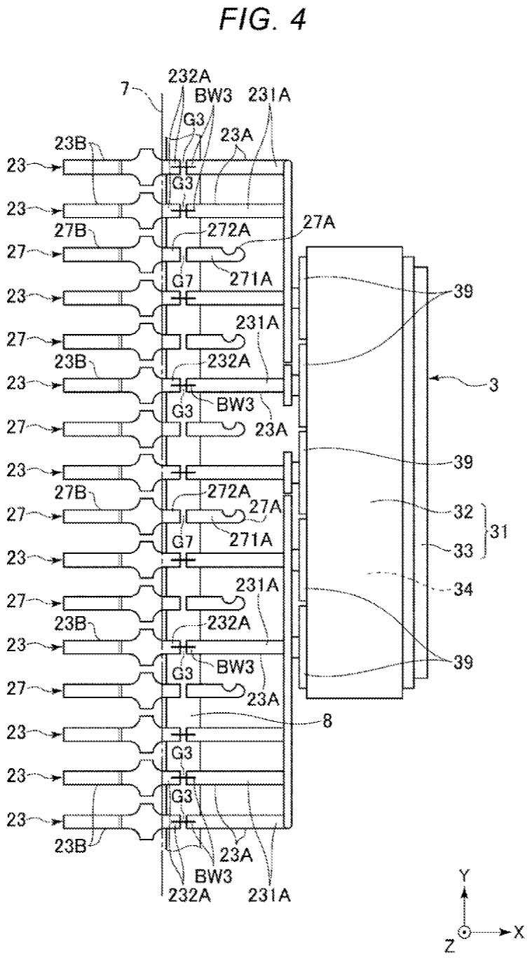

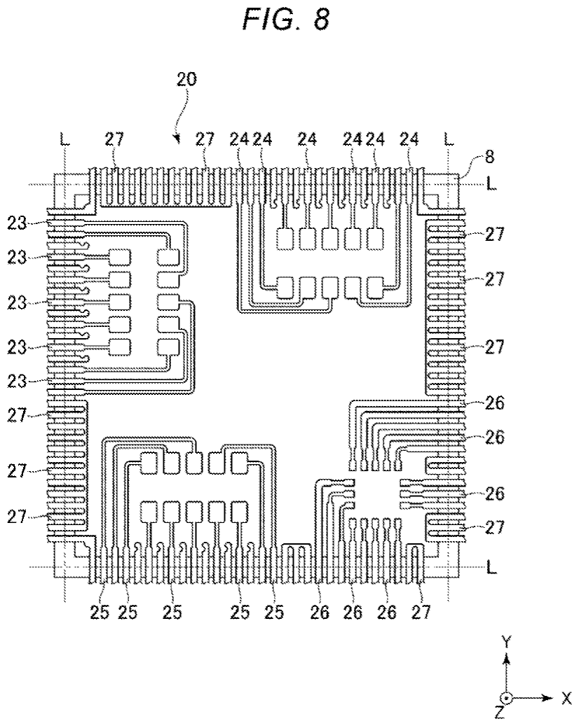

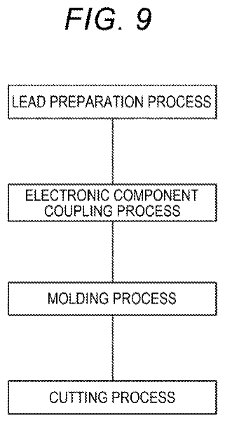

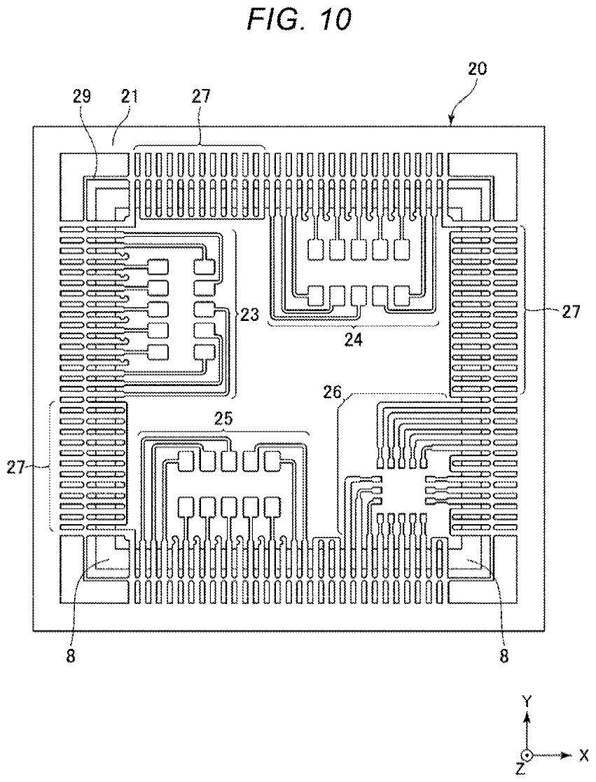

FIG. 1 is a perspective view showing the electronic device. FIG. 2 and FIG. 3 are each a cross-sectional view showing an example of an electronic component. FIG. 4 through FIG. 7 are each a plan view showing the leads. FIG. 8 is a plan view for explaining the method of forming the leads. FIG. 9 is a diagram showing a manufacturing process of the electronic device shown in FIG. 1. FIG. 10 through FIG. 14 are each a diagram for explaining the method of manufacturing the electronic device shown in FIG. 1.

It should be noted that in each of the drawings, there are illustrated three axes perpendicular to each other as an X axis, a Y axis, and a Z axis for the sake of convenience of explanation. A direction parallel to the X axis is also referred to as an “X-axis direction,” a direction parallel to the Y axis is also referred to as a “Y-axis direction,” and a direction parallel to the Z axis is referred to as a “Z-axis direction.” Further, the tip side of an arrow representing each of the axes is also referred to as a “positive side,” and the opposite side is also referred to as a “negative side.” Further, the positive side in the Z-axis direction is also referred to as “above,” and the negative side in the Z-axis direction is also referred to as “below.”

The electronic device 1 has a lead group 2 provided with a plurality of leads, a support 8 for supporting the lead group 2, four electronic components 3, 4, 5, and 6 coupled to the lead group 2, and a mold cover 7 molding the four electronic components 3, 4, 5, and 6.

Further, the electronic components 3, 4, 5, and 6 are each a sensor component. Specifically, among the electronic components 3, 4, 5, and 6, the electronic component 3 is an X-axis angular velocity sensor for detecting the angular velocity around the X axis, the electronic component 4 is a Y-axis angular velocity sensor for detecting the angular velocity around the Y axis, the electronic component 5 is a Z-axis angular velocity sensor for detecting the angular velocity around the Z axis, and the electronic component 6 is a triaxial acceleration sensor for independently detecting the acceleration in the X-axis direction, the acceleration in the Y-axis direction, and the acceleration in the Z-axis direction. In other words, the electronic device 1 according to the present embodiment is a six-axis composite sensor.

It should be noted that the configuration of the electronic device 1 is not limited to the above, but it is also possible to omit any one, two, or three of the electronic components 3, 4, 5, and 6, or it is also possible to add another electronic component. Further, each of the electronic components 3, 4, 5, and 6 is not limited to the sensor component.

Then, the electronic components 3, 4, and 5 will briefly be described. These electronic components 3, 4, and 5 are the same in configuration, and are arranged with a tilt of 90° from each other so that the postures thereof correspond to the respective detection axes. Therefore, the electronic component 3 will hereinafter be described as a representative, and the description of the electronic components 4, 5 will be omitted.

As shown in FIG. 2, the electronic component 3 has a package 31 and a sensor element 34 housed in the package 31. The package 31 is constituted by, for example, abase 32 having a recessed part 321, and a lid 33 bonded to the base 32 so as to close an opening of the recessed part 321. A plurality of external terminals 39 is disposed on a lower surface of the base 32, and the external terminals 39 are each electrically coupled to the sensor element 34. The sensor element 34 is, for example, a quartz crystal vibrator element having drive arms and vibrating arms. When the angular velocity is applied in the state in which the drive arms are made to perform a drive vibration, a detection vibration is excited in the detection arms due to the Coriolis force, and it is possible to obtain the angular velocity based on the charge generated in the detection arms due to the detection vibration.

Although the electronic component 3 is hereinabove described, the configuration of the electronic component 3 is not particularly limited providing the function can be exerted. For example, the sensor element 34 is not limited to the quartz crystal vibrator element, but can also be, for example, a silicon vibrator element, and can be provided with a configuration of detecting the angular velocity based on the variation of the capacitance. Further, although in the present embodiment, the electronic components 3, 4, and 5 are the same in configuration, this is not a limitation, and at least one can be different in configuration from the others.

Then, the electronic component 6 will briefly be described. As shown in FIG. 3, the electronic component 6 has a package 61 and sensor elements 64, 65, and 66 housed in the package 61. The package 61 has abase 62 having recessed parts 624, 625, and 626 formed so as to overlap the sensor elements 64, 65, and 66, and a lid 63 which has a recessed part 631 opening on the base 62 side, and is bonded to the base 62 so as to house the sensor elements 64, 65, and 66 in the recessed part 631. A plurality of external terminals 69 is disposed on a lower surface of the base 62, and the external terminals 69 are each electrically coupled to the sensor elements 64, 65, and 66.

Further, the sensor element 64 is an element for detecting the acceleration in the X-axis direction, the sensor element 65 is an element for detecting the acceleration in the Y-axis direction, and the sensor element 66 is an element for detecting the acceleration in the Z-axis direction. These sensor elements 64, 65, and 66 are each a silicon vibrator element having a stationary electrode, and a movable electrode which forms a capacitance with the stationary electrode, and is displaced with respect to the stationary electrode when the acceleration in the detection axis direction is received. Therefore, it is possible to detect the acceleration in the X-axis direction based on the variation of the capacitance of the sensor element 64, it is possible to detect the acceleration in the Y-axis direction based on the variation of the capacitance of the sensor element 65, and it is possible to detect the acceleration in the Z-axis direction based on the variation of the capacitance of the sensor element 66.

Although the electronic component 6 is hereinabove described, the configuration of the electronic component 6 is not particularly limited providing the function can be exerted. For example, each of the sensor elements 64, 65, and 66 is not limited to the silicon vibrator element, but can also be, for example, a quartz crystal vibrator element, and can be provided with a configuration of detecting the acceleration based on the charge generated by the vibration. It is necessary for the electronic components 3, 4, 5, and 6 to be fixed in a desired position and posture in order to exert the respective functions described above. Therefore, these are fixed by the mold cover 7, and are thus protected.

Then, the lead group 2 will be described. As shown in FIG. 1, the lead group 2 includes a plurality of leads 23 coupled to the electronic component 3, a plurality of leads 24 coupled to the electronic component 4, a plurality of leads 25 coupled to the electronic component 5, and a plurality of leads 26 coupled to the electronic component 6. Further, the lead group 2 includes a plurality of leads 27 electrically coupled to none of the electronic components 3, 4, 5, and 6.

Further, the electronic component 3 and each of the leads 23, the electronic component 4 and each of the leads 24, the electronic component 5 and each of the leads 25, and the electronic component 6 and each of the leads 26 are each coupled mechanically and electrically to each other via an electrically conductive bonding material (not shown) such as solder. Further, one end of each of the leads 23, 24, 25, 26, and 27 projects outside the mold cover 7, and attachment to an external device is achieved in these parts. Hereinafter, a part located inside the mold cover 7 of each of the leads 23, 24, 25, 26, and 27 is also referred to as an “inner part,” and a part thereof located outside the mold cover 7 is also referred to as an “outer part” for the sake of convenience of explanation.

Further, the lead group 2 is generally arranged along an X-Y plane including the X axis and the Y axis. Further, each of the leads 23 coupled to the electronic component 3 is folded as much as 90° toward the Z-axis direction in the middle of the lead 23 in order to make the detection axis of the electronic component 3 coincide with the X axis. Similarly, each of the leads 24 coupled to the electronic component 4 is folded as much as 90° toward the Z-axis direction in the middle of the lead 24 in order to make the detection axis of the electronic component 4 coincide with the Y axis. In contrast, each of the leads 25 coupled to the electronic component 5 and each of the leads 26 coupled to the electronic component 6 are not folded like the leads 23, 24, but extend along the X-Y plane. Each of the leads 27 coupled to none of the electronic components 3, 4, 5, and 6 is not folded like the leads 23, 24, but extends along the X-Y plane.

Further, as shown in FIG. 4, the inner part 23A of each of the leads 23 has a first lead 231A coupled to the electronic component 3, and a second lead 232A separated from the first lead 231A and integrated with the outer part 23B. Further, the first lead 231A and the second lead 232A are electrically coupled to each other via a bonding wire BW3 as a coupling member. In other words, the inner part 23A is structurally divided into two structures in the middle thereof, and these two structures are electrically coupled to each other via the bonding wire BW3. In particular, in the present embodiment, since ends of the first and second leads 231A, 232A are opposed to each other, namely opposed right to each other, coupling with the bonding wire BW3 becomes easy.

By structurally separating the first lead 231A and the outer part 23B from each other as described above, the vibration and the impact to be propagated from the external device to the outer part 23B become difficult to propagate to the first lead 231A. In other words, the gap G3 fulfills a buffering function. Therefore, the electronic component 3 becomes difficult to be affected by the vibration and so on, and it is possible to effectively suppress the deterioration of the characteristics and breakage of the electronic component 3. In particular, in the present embodiment, the sensor element 34 provided to the electronic component 3 is the quartz crystal vibrator element (a piezoelectric element) easy to be affected by resonance, and there is a possibility that the resonance of the lead 23 deteriorates the characteristics of the quartz crystal vibrator element. In this regard, by structurally separating the first lead 231A and the outer part 23B from each other, the first lead 231A becomes difficult to resonate, and thus, it is possible to effectively suppress the deterioration of the characteristics of the sensor element 34.

Further, there is a possibility that the moisture infiltrates inside the mold cover 7 from the outside of the electronic device 1 via a minute gap which can occur on the boundary between the mold cover 7 and each of the leads 23. In this regard, by dividing the inner part 23A into the first lead 231A and the second lead 232A, the mold material enters the gap G3 between them to form a barrier against the moisture infiltration, and thus, it is possible to effectively prevent the moisture from infiltrating into the back of the second lead 232A. Therefore, it is possible to effectively prevent the deterioration and a decrease in performance of the electronic component 3, breakage of the mold cover 7, and so on due to the moisture.

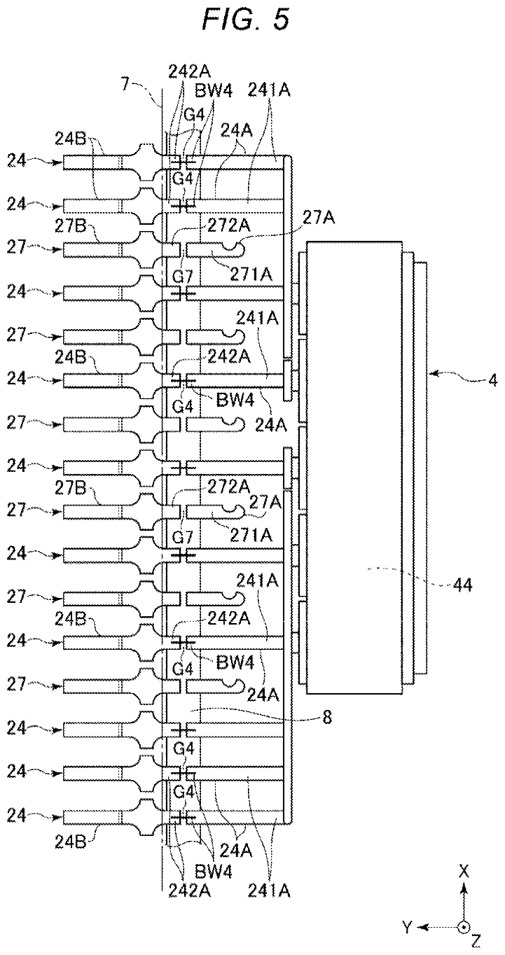

Each of the leads 24 has substantially the same configuration as that of each of the leads 23 described above. Specifically, as shown in FIG. 5, the inner part 24A of each of the leads 24 has a first lead 241A coupled to the electronic component 4, and a second lead 242A separated from the first lead 241A and integrated with the outer part 24B. Further, the first lead 241A and the second lead 242A are electrically coupled to each other via a bonding wire BW4 as a coupling member. In other words, the inner part 24A is structurally divided into two structures in the middle thereof, and these two structures are electrically coupled to each other via the bonding wire BW4. In particular, in the present embodiment, since ends of the first and second leads 241A, 242A are opposed to each other, coupling with the bonding wire BW4 becomes easy.

By structurally separating the first lead 241A and the outer part 24B from each other as described above, the vibration and the impact to be propagated from the external device to the outer part 24B become difficult to propagate to the first lead 241A. In other words, the gap G4 fulfills a buffering function. Therefore, the electronic component 4 becomes difficult to be affected by the vibration and so on, and it is possible to effectively suppress the deterioration of the characteristics and breakage of the electronic component 4. In particular, in the present embodiment, the sensor element 44 provided to the electronic component 4 is the quartz crystal vibrator element (a piezoelectric element) easy to be affected by resonance, and there is a possibility that the resonance of the lead 24 deteriorates the characteristics of the quartz crystal vibrator element. In this regard, by structurally separating the first lead 241A and the outer part 24B from each other, the first lead 241A becomes difficult to resonate, and thus, it is possible to effectively suppress the deterioration of the characteristics of the sensor element 44.

Further, there is a possibility that the moisture infiltrates inside the mold cover 7 from the outside of the electronic device 1 via a minute gap which can occur on the boundary between the mold cover 7 and each of the leads 24. In this regard, by dividing the inner part 24A into the first lead 241A and the second lead 242A, the mold material enters the gap G4 between them to form a barrier against the moisture infiltration, and thus, it is possible to effectively prevent the moisture from infiltrating into the back of the second lead 242A. Therefore, it is possible to effectively prevent the deterioration and a decrease in performance of the electronic component 4, breakage of the mold cover 7, and so on due to the moisture.

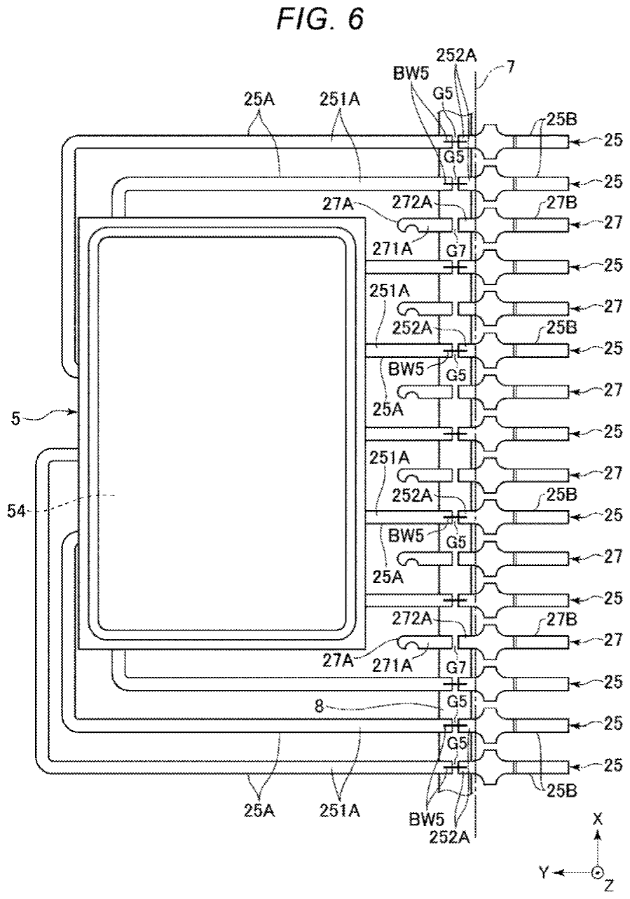

Each of the leads 25 has substantially the same configuration as that of each of the leads 23 described above. Specifically, as shown in FIG. 6, the inner part 25A of each of the leads 25 has a first lead 251A coupled to the electronic component 5, and a second lead 252A separated from the first lead 251A and integrated with the outer part 25B. Further, the first lead 251A and the second lead 252A are electrically coupled to each other via a bonding wire BW5 as a coupling member. In other words, the inner part 25A is structurally divided into two structures in the middle thereof, and these two structures are electrically coupled to each other via the bonding wire BW5. In particular, in the present embodiment, since ends of the first and second leads 251A, 252A are opposed to each other, coupling with the bonding wire BW5 becomes easy.

By structurally separating the first lead 251A and the outer part 25B from each other as described above, the vibration and the impact to be propagated from the external device to the outer part 25B become difficult to propagate to the first lead 251A. In other words, the gap G5 fulfills a buffering function. Therefore, the electronic component 5 becomes difficult to be affected by the vibration and so on, and it is possible to effectively suppress the deterioration of the characteristics and breakage of the electronic component 5. In particular, in the present embodiment, the sensor element 54 provided to the electronic component 5 is the quartz crystal vibrator element (a piezoelectric element) easy to be affected by resonance, and there is a possibility that the resonance of the lead 25 deteriorates the characteristics of the quartz crystal vibrator element. In this regard, by structurally separating the first lead 251A and the outer part 25B from each other, the first lead 251A becomes difficult to resonate, and thus, it is possible to effectively suppress the deterioration of the characteristics of the sensor element 54.

Further, there is a possibility that the moisture infiltrates inside the mold cover 7 from the outside of the electronic device 1 via a minute gap which can occur on the boundary between the mold cover 7 and each of the leads 25. In this regard, by dividing the inner part 25A into the first lead 251A and the second lead 252A, the mold material enters the gap G5 between them to form a barrier against the moisture infiltration, and thus, it is possible to effectively prevent the moisture from infiltrating into the back of the second lead 252A. Therefore, it is possible to effectively prevent the deterioration and a decrease in performance of the electronic component 5, breakage of the mold cover 7, and so on due to the moisture.

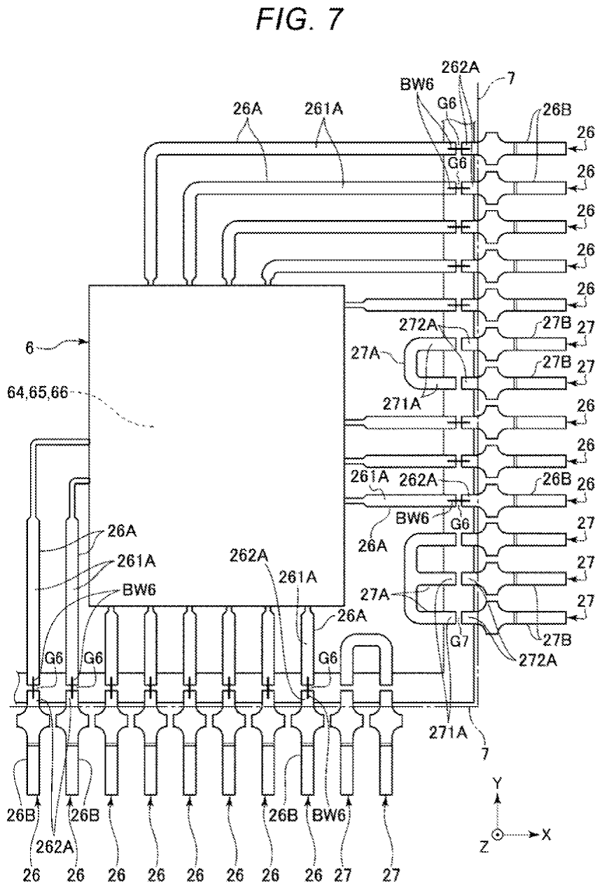

Each of the leads 26 has substantially the same configuration as that of each of the leads 23 described above. Specifically, as shown in FIG. 7, the inner part 26A of each of the leads 26 has a first lead 261A coupled to the electronic component 6, and a second lead 262A separated from the first lead 261A and integrated with the outer part 26B. Further, the first lead 261A and the second lead 262A are electrically coupled to each other via a bonding wire BW6 as a coupling member. In other words, the inner part 26A is structurally divided into two structures in the middle thereof, and these two structures are electrically coupled to each other via the bonding wire BW6. In particular, in the present embodiment, since ends of the first and second leads 261A, 262A are opposed to each other, coupling with the bonding wire BW6 becomes easy.

By structurally separating the first lead 261A and the outer part 26B from each other as described above, the vibration and the impact to be propagated from the external device to the outer part 26B become difficult to propagate to the first lead 261A. In other words, the gap G6 fulfills a buffering function. Therefore, since the electronic component 6 becomes difficult to be affected by the vibration and so on, it is possible to effectively suppress the deterioration of the characteristics and breakage of the electronic component 6.

Further, there is a possibility that the moisture infiltrates inside the mold cover 7 from the outside of the electronic device 1 via a minute gap which can occur on the boundary between the mold cover 7 and each of the leads 26. In this regard, by dividing the inner part 26A into the first lead 261A and the second lead 262A, the mold material enters the gap G6 between them to form a barrier against the moisture infiltration, and thus, it is possible to effectively prevent the moisture from infiltrating into the back of the second lead 262A. Therefore, it is possible to effectively prevent the deterioration of the electronic component 6, breakage of the mold cover 7, and so on due to the moisture.

Each of the leads 27 has a slightly different configuration from that of each of the leads 23 described above. As shown in FIG. 4 through FIG. 7, the inner part 27A of each of the leads 27 has a first lead 271A coupled to none of the electronic components 3, 4, 5, and 6, and a second lead 272A separated from the first lead 271A and integrated with the outer part 27B. Further, unlike the leads 23, the bonding wire is omitted, and the first lead 271A and the second lead 272A are electrically separated from each other.

By structurally dividing the inner part 27A into two parts in the middle thereof as described above with respect to each of the leads 27 coupled to none of the electronic components 3, 4, 5, and 6, formation of the lead group 2 becomes easy. In other words, the lead group 2 can more easily be formed by dividing all of the leads 23, 24, 25, 26, and 27 in a lump compared to dividing only the leads 23, 24, 25, and 26 except the leads 27 out of all of the leads 23, 24, 25, 26, and 27.

Further, there is a possibility that the moisture infiltrates inside the mold cover 7 from the outside of the electronic device 1 via a minute gap which can occur on the boundary between the mold cover 7 and each of the leads 27. In this regard, by dividing the inner part 27A into the first lead 271A and the second lead 272A, the mold material enters the gap G7 between them to form a barrier against the moisture infiltration, and thus, it is possible to effectively prevent the moisture from infiltrating into the back of the second lead 272A. In particular, since the bonding wire for coupling the first lead 271A and the second lead 272A to each other is omitted, the advantage described above becomes more conspicuous.

In particular, in the present embodiment, the gaps G3 each located between the first lead 231A and the second lead 232A of each of the leads 23, the gaps G4 each located between the first lead 241A and the second lead 242A of each of the leads 24, the gaps G5 each located between the first lead 251A and the second lead 252A of each of the leads 25, the gaps G6 each located between the first lead 261A and the second lead 262A of each of the leads 26, and the gaps G7 each located between the first lead 271A and the second lead 272A of each of the leads 27 are arranged in a line along the outer edge part of the mold cover 7 so as to forma frame-like shape. By arranging the gaps G3, G4, G5, G6, and G7 in a line, it becomes easy to form the lead group 2.

The method of forming the lead group 2 will be described citing an example. Firstly, as shown in FIG. 8, a lead frame 20 including the leads 23, 24, 25, 26, and 27 supported by the support 8, and each having the inner part undivided is prepared. Then, each of the leads 23, 24, 25, 26, and 27 is cut along the line set at a position overlapping the support 8 using a dicing saw or the like. Thus, each of the inner parts 23A, 24A, 25A, 26A, and 27A is divided into the first lead 231A, 241A, 251A, 261A, or 271A and the second lead 232A, 242A, 252A, 262A, or 272A. By arranging the gaps G3, G4, G5, G6, and G7 in a line, it is possible to cut the inner parts of the plurality of leads in a lump, and therefore, it is possible to reduce the number of times of cutting with the dicing saw, and accordingly, it becomes easy to form the lead group 2. In particular, since the part extending along the X-Y plane of each of the leads 23, 24, 25, 26, and 27 is cut, coupling with the bonding wires BW3, BW4, BW5, and BW6 to subsequently be performed becomes easy. Although in the present embodiment, the leads 23, 24, 25, 26, and 27 each include the first lead and the second lead separated from each other, this is not a limitation, and it is sufficient for the present configuration to be fulfilled by at least one of the leads 23, 24, 25, and 26.

The support 8 supports the lead group 2. Specifically, the support 8 forms a frame-like shape located inside the mold cover 7, and supports the end of each of the first leads 231A, 241A, 251A, 261A, and 271A of the leads 23, 24, 25, 26, and 27 and the end of each of the second leads 232A, 242A, 252A, 262A, and 272A thereof as shown in FIG. 4 through FIG. 7. Further, the first leads 231A, 241A, 251A, 261A, and 271A project inside the support 8, and the second leads 232A, 242A, 252A, 262A, and 272A project outside the support 8. According to such a support 8, it is possible to fix the first leads 231A, 241A, 251A, 261A, and 271A and the second leads 232A, 242A, 252A, 262A, and 272A to each other so as not to be discretely disposed before being covered with the mold cover 7. It should be noted that the configuration of the support 8 is not particularly limited. Further, the support 8 can also be omitted.

Further, the constituent material of the support 8 is preferably the same as the constituent material of the mold cover 7, namely the mold material. Thus, affinity between the support 8 and the mold cover 7 increases, and the adhesiveness therebetween is improved. Further, the thermal expansion coefficients of the support 8 and the mold cover 7 can be made substantially equal to each other, and thus the distortion due to the thermal stress can effectively be prevented from occurring. Therefore, the electronic components 3, 4, 5, and 6 can more effectively be protected from the moisture, and at the same time, a variation of the characteristics of the electronic components 3, 4, 5, and 6 due to the ambient temperature can effectively be suppressed. It should be noted that this is not a limitation, and it is also possible for the constituent material of the support 8 to be different from the constituent material of the mold cover 7.

The mold cover 7 molds the electronic components 3, 4, 5, and 6 to protect them from moisture, dust, an impact, and so on. The mold material for constituting the mold cover 7 is not particularly limited, but it is also possible to use a curing resin material such as thermosetting epoxy resin, and it is possible to form the mold using a transfer molding method.

The configuration of the electronic device 1 is hereinabove described. As described above, such an electronic device 1 includes the electronic components 3, 4, 5, and 6, the leads 23, 24, 25, and 26 electrically coupled to the electronic components 3, 4, 5, and 6, and the mold cover 7 for covering the electronic components 3, 4, 5, and 6. Further, the leads 23, 24, 25, and 26 each have the inner part 23A, 24A, 25A, or 26A located inside the mold cover 7, and the outer part 23B, 24B, 25B, or 26B located outside the mold cover 7. Further, the inner part 23A has the first lead 231A electrically coupled to the electronic component 3, the second lead 232A separated from the first lead 231A and integrated with the outer part 23B, and the bonding wire BW3 as a coupling member for electrically coupling the first lead 231A and the second lead 232A to each other. Further, the inner part 24A has the first lead 241A electrically coupled to the electronic component 4, the second lead 242A separated from the first lead 241A and integrated with the outer part 24B, and the bonding wire BW4 as a coupling member for electrically coupling the first lead 241A and the second lead 242A to each other. Further, the inner part 25A has the first lead 251A electrically coupled to the electronic component 5, the second lead 252A separated from the first lead 251A and integrated with the outer part 25B, and the bonding wire BW5 as a coupling member for electrically coupling the first lead 251A and the second lead 252A to each other. Further, the inner part 26A has the first lead 261A electrically coupled to the electronic component 6, the second lead 262A separated from the first lead 261A and integrated with the outer part 26B, and the bonding wire BW6 as a coupling member for electrically coupling the first lead 261A and the second lead 262A to each other.

By structurally separating the first leads 231A, 241A, 251A, and 261A from the outer parts 23B, 24B, 25B, and 26B, respectively, as described above, the vibration to be propagated from the external device to the outer parts 23B, 24B, 25B, and 26B becomes difficult to propagate to the first leads 231A, 241A, 251A, and 261A, respectively. Therefore, the electronic components 3, 4, 5, and 6 become difficult to be affected by the vibration, and it is possible to effectively suppress the deterioration of the characteristics and breakage of the electronic components 3, 4, 5, and 6. In particular, in the present embodiment, the sensor elements 34, 44, 45, and 46 respectively provided to the electronic components 3, 4, 5, and 6 are each the quartz crystal vibrator element, namely the piezoelectric element, easy to be affected by resonance, and there is a possibility that the resonance of the leads 23, 24, and 25 deteriorates the characteristics of the quartz crystal vibrator element. In this regard, by structurally separating the first leads 231A, 241A, and 251A and the outer parts 23B, 24B, and 25B from each other, respectively, the first leads 231A, 241A, and 251A become difficult to resonate, and thus, it is possible to effectively suppress the deterioration of the characteristics of the sensor elements 34, 44, and 54.

Further, there is a possibility that the moisture infiltrates inside the mold cover 7 from the outside of the electronic device 1 via the minute gap which can occur on the boundary between the mold cover 7 and each of the leads 23, 24, 25, and 26. In this regard, by dividing the inner parts 23A, 24A, 25A, and 26A into the first leads 231A, 241A, 251A, and 261A and the second leads 232A, 242A, 252A, and 262A, respectively, the mold material entering the gaps G3, G4, G5, and G6 therebetween act as barriers, and it is possible to effectively prevent the moisture from infiltrating into the back of the second leads 232A, 242A, 252A, and 262A, respectively. Therefore, it is possible to effectively prevent the deterioration and the decrease in performance of the electronic components 3, 4, 5, and 6, breakage of the mold cover 7, and so on due to the moisture.

Further, as described above, the coupling members for electrically coupling the first leads 231A, 241A, 251A, and 261A and the second leads 232A, 242A, 252A, and 262A to each other, respectively, are the bonding wires BW3, BW4, BW5, and BW6. Thus, the configuration of the coupling members is simplified. It should be noted that the coupling members are not limited to the bonding wires.

Further, as described above, the electronic device 1 has the plurality of leads 23 coupled to the electronic component 3, and each of the leads 23 has the first lead 231A and the second lead 232A. Further, the electronic device 1 has the plurality of leads 24 coupled to the electronic component 4, and each of the leads 24 has the first lead 241A and the second lead 242A. Further, the electronic device 1 has the plurality of leads 25 coupled to the electronic component 5, and each of the leads 25 has the first lead 251A and the second lead 252A. Further, there is provided the plurality of leads 26 coupled to the electronic component 6, and each of the leads 26 has the first lead 261A and the second lead 262A. By dividing all of the leads 23, 24, 25, and 26 into the first leads and the second leads as described above, the advantage described above becomes more conspicuous. Specifically, the electronic components 3, 4, 5, and 6 become more difficult to be affected by the vibration, and it is possible to effectively suppress the deterioration of the characteristics and breakage of the electronic components 3, 4, 5, and 6. Further, it is possible to more effectively prevent the deterioration of the electronic components 3, 4, 5, and 6, breakage of the mold cover 7, and so on due to the moisture.

It should be noted that this is not a limitation, it is sufficient that at least one of the leads 23, 24, 25 and 26 is divided into the first lead and the second lead, and for example, the lead which is not divided into the first lead and the second lead can be included in the plurality of leads 23, 24, 25, and 26.

Further, as described above, the gaps G3, G4, G5, G6, and G7 located between the first leads and the second leads of the plurality of leads 23, 24, 25, 26, and 27, respectively, are arranged in a line. Thus, it becomes easy to form the leads 23, 24, 25, 26, and 27. It should be noted that this is not a limitation, and it is not required for the gaps G3, G4, G5, G6, and G7 to be arranged in a line.

Further, as described above, the end at the second lead 232A side of the first lead 231A of each of the leads 23 and the end at the first lead 231A side of the second lead 232A are opposed to each other. Thus, the coupling with the bonding wires BW3 becomes easy. Similarly, the end at the second lead 242A side of the first lead 241A of each of the leads 24 and the end at the first lead 241A side of the second lead 242A are opposed to each other. Thus, the coupling with the bonding wires BW4 becomes easy. Similarly, the end at the second lead 252A side of the first lead 251A of each of the leads 25 and the end at the first lead 251A side of the second lead 252A are opposed to each other. Thus, the coupling with the bonding wires BW5 becomes easy. Similarly, the end at the second lead 262A side of the first lead 261A of each of the leads 26 and the end at the first lead 261A side of the second lead 262A are opposed to each other. Thus, the coupling with the bonding wires BW6 becomes easy.

Further, as described above, the electronic device 1 has the support 8 for supporting the first leads 231A, 241A, 251A, 261A, and 271A and the second leads 232A, 242A, 252A, 262A, and 272A. Thus, it is possible to fix the first leads 231A, 241A, 251A, 261A, and 271A and the second leads 232A, 242A, 252A, 262A, and 272A to each other so as not to be discretely disposed before being covered with the mold cover 7. Therefore, it becomes easy to manufacture the electronic device 1.

Further, as described above, the constituent material of the support 8 is the same as the constituent material of the mold cover 7. Thus, affinity between the support 8 and the mold cover 7 increases, and the adhesiveness therebetween is improved. Further, the thermal expansion coefficients of the support 8 and the mold cover 7 can be made substantially equal to each other, and thus the distortion due to the thermal stress can effectively be prevented from occurring. Therefore, the electronic components 3, 4, 5, and 6 can more effectively be protected from the moisture, and at the same time, a variation of the characteristics of the electronic components 3, 4, 5, and 6 due to the ambient temperature can effectively be suppressed.

Further, as described above, the electronic component 3 is a sensor component provided with the sensor element 34 as the vibrator element. Further, the electronic component 4 is a sensor component provided with the sensor element 44 as the vibrator element. Further, the electronic component 5 is a sensor component provided with the sensor element 54 as the vibrator element. Further, the electronic component 6 is a sensor component provided with the sensor elements 64, 65, and 66 as the vibrator elements. The electronic components 3, 4, 5, and 6 having such a configuration are particularly easy to be affected by a vibration. Therefore, by applying such a separation structure as described above to the leads 23, 24, 25, and 26 coupled to the electronic components 3, 4, 5, and 6, it is possible to more significantly exert the advantages.

Further, as described above, the leads 23 each have the first lead 231A electrically coupled to the electronic component 3, the second lead 232A separated from the first lead 231A, and the bonding wire BW3 as a coupling member for electrically coupling the first lead 231A and the second lead 232A to each other. Thus, there are achieved the leads 23 difficult to propagate a vibration to the electronic component 3, and it is possible to more effectively prevent the degradation of the characteristics of the electronic component 3 caused by the vibration.

Similarly, the leads 24 each have the first lead 241A electrically coupled to the electronic component 4, the second lead 242A separated from the first lead 241A, and the bonding wire BW4 as a coupling member for electrically coupling the first lead 241A and the second lead 242A to each other. Thus, there are achieved the leads 24 difficult to propagate a vibration to the electronic component 4, and it is possible to more effectively prevent the degradation of the characteristics of the electronic component 4 caused by the vibration.

Similarly, the leads 25 each have the first lead 251A electrically coupled to the electronic component 5, the second lead 252A separated from the first lead 251A, and the bonding wire BW5 as a coupling member for electrically coupling the first lead 251A and the second lead 252A to each other. Thus, there are achieved the leads 25 difficult to propagate a vibration to the electronic component 5, and it is possible to more effectively prevent the degradation of the characteristics of the electronic component 5 caused by the vibration.

Similarly, the leads 26 each have the first lead 261A electrically coupled to the electronic component 6, the second lead 262A separated from the first lead 261A, and the bonding wire BW6 as a coupling member for electrically coupling the first lead 261A and the second lead 262A to each other. Thus, there are achieved the leads 26 difficult to propagate a vibration to the electronic component 6, and it is possible to more effectively prevent the degradation of the characteristics of the electronic component 6 caused by the vibration.

Then, a method of manufacturing the electronic device 1 will be described. As shown in FIG. 9, the manufacturing process of the electronic device 1 includes a lead preparation process of preparing the lead group 2, an electronic component coupling process of coupling the electronic components 3, 4, 5, and 6 to the lead group 2, a molding process of forming the mold cover for covering the electronic components 3, 4, 5, and 6, and a cutting process of cutting the leads 23, 24, 25, 26, and 27.

### Lead Preparation Process

Firstly, as shown in FIG. 10, the lead frame 20 is prepared. The lead frame 20 has a frame 21 having a frame-like shape, the plurality of leads 23, 24, 25, 26, and 27 located inside the frame 21 and supported by the frame 21, and tie bars 29 coupling the leads 23, 24, 25, 26, and 27 to each other. Further, to the lead frame 20, there is attached the support 8 for supporting the leads 23, 24, 25, 26, and 27.

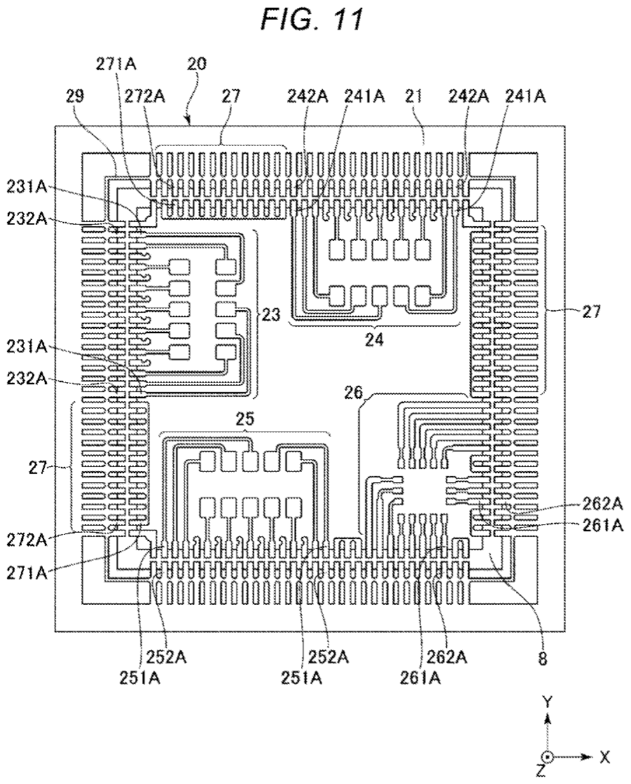

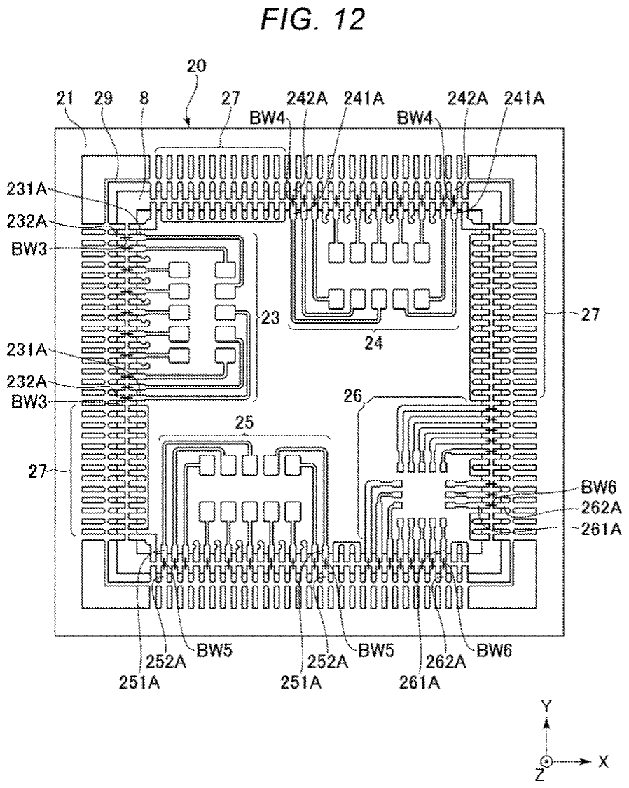

Then, as shown in FIG. 11, the leads 23, 24, 25, 26, and 27 are cut in the portions supported by the support 8 using a dicing saw or the like to form the first leads 231A, 241A, 251A, 261A, and 271A and the second leads 232A, 242A, 252A, 262A, and 272A. Then, as shown in FIG. 12, the first leads 231A, 241A, 251A, and 261A and the second leads 232A, 242A, 252A, and 262A are electrically coupled to each other with the bonding wires BW3, BW4, BW5, and BW6, respectively.

### Electronic Component Coupling Process

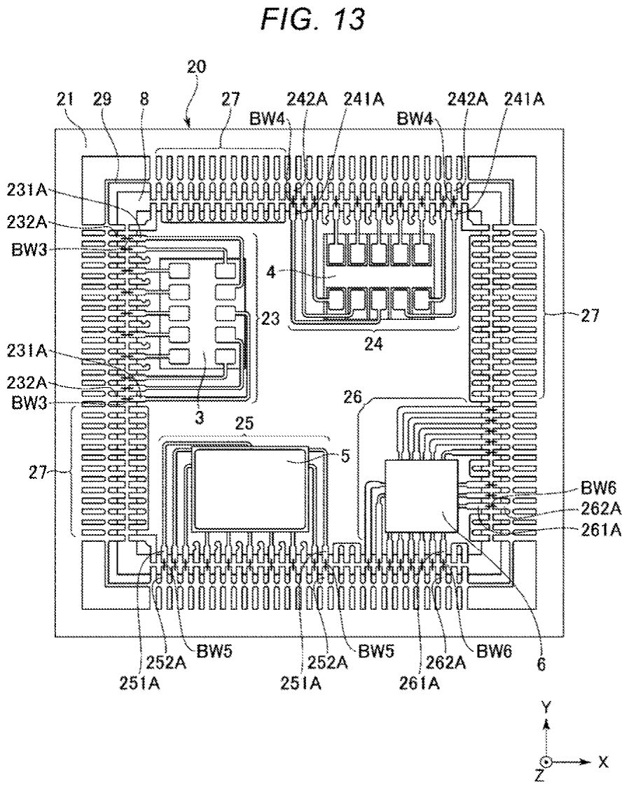

Then, as shown in FIG. 13, the electronic component 3 is coupled to the first leads 231A of the plurality of leads 23 via the bonding material, the electronic component 4 is coupled to the first leads 241A of the plurality of leads 24 via the bonding material, the electronic component 5 is coupled to the first leads 251A of the plurality of leads 25 via the bonding material, and the electronic component 6 is coupled to the first leads 261A of the plurality of leads 26 via the bonding material.

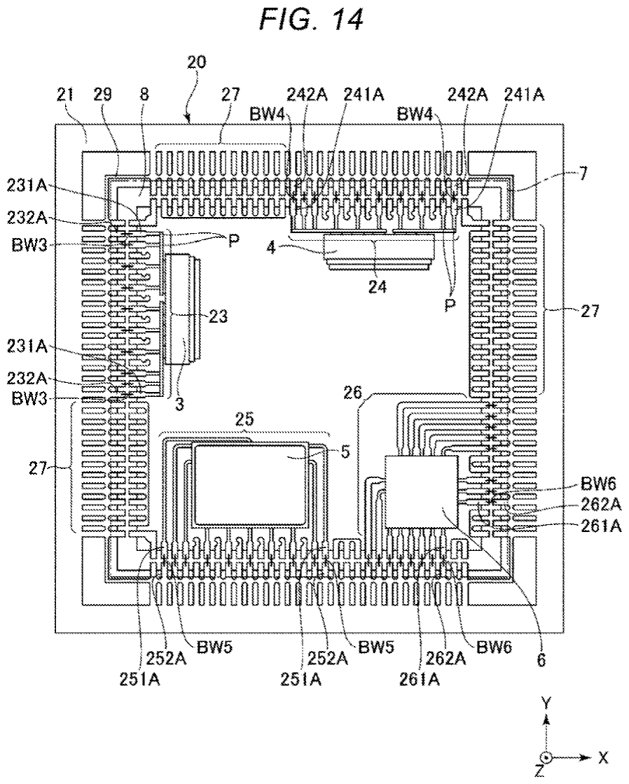

Then, as shown in FIG. 14, the plurality of leads 23 is each folded 90° toward the positive side in the Z-axis direction at a folding point P in the middle of the first lead 231A to erect the electronic component 3 to make the detection axis of the electronic component 3 coincide with the X axis. Further, the plurality of leads 24 is each folded 90° toward the positive side in the Z-axis direction at a folding point P in the middle of the first lead 241A to erect the electronic component 4 to make the detection axis of the electronic component 4 coincide with the Y axis.

### Molding Process

Then, the electronic components 3, 4, 5, and 6 are covered with a metal mold, and the mold cover 7 covering the electronic components 3, 4, 5, and 6 is formed using transfer molding as shown in FIG. 14. Specifically, the electronic components 3, 4, 5, and 6 are disposed inside the metal mold, then the metal mold is filled with the mold material melted or softened, and then curing of the mold material and separation thereof from the metal mold are performed. Thus, the electronic components 3, 4, 5, and 6 are each fixed at a desired position and in a desired posture. Further, the gaps G3, G4, G5, and G6 are each filled with the mold material, and it is possible to prevent the moisture and a foreign matter from infiltrating into the mold cover 7.

### Cutting Process

Then, the frame 21 is removed from the lead frame 20, and the outer parts 23B, 24B, 25B, 26B, and 27B of the leads 23, 24, 25, 26, and 27 are folded into predetermined shapes. Subsequently, the tie bars 29 for coupling the leads 23, 24, 25, 26, and 27 to each other are cut by a laser or the like. According to the process described hereinabove, the electronic device 1 shown in FIG. 1 is manufactured.

As described above, the method of manufacturing the electronic device 1 includes the process of preparing the leads 23, 24, 25, and 26 respectively having the first leads 231A, 241A, 251A, and 261A, the second leads 232A, 242A, 252A, and 262A respectively separated from the first leads 231A, 241A, 251A, and 261A, and the bonding wires BW3, BW4, BW5, and BW6 as the coupling members for electrically coupling the first leads 231A, 241A, 251A, and 261A and the second leads 232A, 242A, 252A, and 262A to each other, respectively, the process of coupling the electronic components 3, 4, 5, and 6 to the first leads 231A, 241A, 251A, and 261A of the leads 23, 24, 25, and 26, respectively, and the process of molding the electronic components 3, 4, 5, and 6 with the resin material.

According to such a manufacturing method as described above, it is possible to more easily manufacture the electronic device 1 difficult for the electronic components 3, 4, 5, and 6 to be affected by the vibration.

Although the electronic device, the method of manufacturing the electronic device, and the lead according to the present disclosure are hereinabove described based on the embodiment shown in the drawings, the present disclosure is not limited to the embodiment, but the constituents of each of the sections can be replaced with those having an identical function and an arbitrary configuration. Further, it is also possible to add any other constituents to the present disclosure.

What is claimed is:

1. An electronic device comprising:
an electronic component;
a plurality of leads electrically coupled to the electronic component; and
a mold cover covering the electronic component, wherein
the plurality of leads includes
an inner part located inside the mold cover, and
an outer part located outside the mold cover, and
the inner part includes
a first lead electrically coupled to the electronic component,
a second lead separated from the first lead and integrated with the outer part, and
a coupling member configured to electrically couple the first lead and the second lead to each other.

2. The electronic device according to claim 1, wherein
the coupling member is a bonding wire.

3. The electronic device according to claim 1, wherein
gaps between the first lead and the second lead of the plurality of leads are arranged in a line.

4. The electronic device according to claim 1, wherein
an end at the second lead side of the first lead and an end at the first lead side of the second lead are opposed to each other.

5. The electronic device according to claim 1, further comprising:
a support configured to support the first lead and the second lead.

6. The electronic device according to claim 5, wherein
a constituent material of the support is same as a constituent material of the mold cover.

7. The electronic device according to claim 1, wherein
the electronic component is a sensor component having a vibrator element.

8. A method of manufacturing an electronic device comprising:
preparing a plurality of leads including a first lead, a second lead separated from the first lead, and a coupling member configured to electrically couple the first lead and the second lead to each other;
electrically coupling the electronic component to the first lead of the plurality of leads; and
molding the electronic component, the first lead, the coupling member, and the second lead with a resin material.

9. The method of manufacturing the electronic device according to claim 8, wherein
the coupling member is a bonding wire.

10. The method of manufacturing the electronic device according to claim 8, wherein
gaps between the first lead and the second lead of the plurality of leads are arranged in a line.

11. The method of manufacturing the electronic device according to claim 8, wherein
an end at the second lead side of the first lead and an end at the first lead side of the second lead are opposed to each other.

12. The method of manufacturing the electronic device according to claim 8, further comprising:
providing a support configured to support the first lead and the second lead.

13. The method of manufacturing the electronic device according to claim 12, wherein
a constituent material of the support is same as the resin material.

14. A lead frame comprising:
a plurality of leads including
a first lead to be electrically coupled to an electronic component,
a second lead separated from the first lead, and
a coupling member configured to electrically couple the first lead and the second lead to each other.

15. The lead frame according to claim 14, wherein
the coupling member is a bonding wire.

16. The lead frame according to claim 14, wherein
gaps between the first lead and the second lead of the plurality of leads are arranged in a line.

17. The lead frame according to claim 14, wherein
an end at the second lead side of the first lead and an end at the first lead side of the second lead are opposed to each other.

18. The lead frame according to claim 14, further comprising:
a support configured to support the first lead and the second lead.
